(19) United States
(12) Patent Application Publication
(10) Pub. No.: US 2015/0162459 A1
(43) Pub. Date: Jun. 11, 2015

(54) SOLAR CELL ANTI REFLECTIVE COATING AND WET CHEMICAL METHOD FOR FORMING THE SAME

(71) Applicants: Wei-Lun LU, Tainan City (TW); Chun-Ying HUANG, Taichung City (TW); Wei-Lun XU, Taipei City (TW)

(72) Inventors: Wei-Lun LU, Tainan City (TW); Chun-Ying HUANG, Taichung City (TW); Wei-Lun XU, Taipei City (TW)

(73) Assignee: TSMC Solar Ltd., Taichung City (TW)

(21) Appl. No.: 14/102,550

(22) Filed: Dec. 11, 2013

(51) Int. Cl. H01L 31/0216; H01L 31/18

(52) U.S. Cl. CPC H01L 31/02168; H01L 31/18

(57) ABSTRACT

Provided are methods for forming antireflective layers on solar cells using wet chemical processes and solar cells with anti-reflective layers formed of ZnO based nanorods. Self-assembling ZnO nanorods are generated in the chemical solution without any catalysts. The nanorods are formed to different shapes such as hexagonal, cubic, and circular in cross-section. The refractive index of the ARC layer formed of the nanorods is modulated by controlling the diameter and length of the nanorods by controlling the Molarity of the solution used to form the nanorods. A correlation is established between the refractive index and solution Molarity and a solution is prepared with the desired Molarity. The nanorods are formed from HMT ([CH₂]₆NH₄) and a dissociative Zn²⁺/OH⁻ chemical such as Zn(NO3)2.

### TECHNICAL FIELD

The disclosure relates, most generally, to solar cells and methods for forming the same. More particularly, the disclosure relates to anti-reflective coatings for solar cells that are formed using wet chemical processes that form nanorods that combine to form the anti-reflective coating (“ARC”).

### BACKGROUND

Solar cells are photovoltaic components for direct generation of electrical current from sunlight. Due to the growing demand for clean sources of energy, the manufacture of solar cells has expanded dramatically in recent years and continues to expand. Various types of solar cells exist and continue to be developed. Solar cells include absorber layers that absorb the sunlight that is converted into electrical current. The quality and performance of the absorber layer is therefore of paramount importance. Further, the amount of available sunlight that actually reaches the absorber layer is of critical importance. It is naturally desirable to avoid reflection of sunlight off a solar cell surface, because the reflected sunlight does not reach the absorber layer and is not converted into electrical energy.

Solar cells typically include one or more layers or materials formed over the absorber layer. A TCO, transparent conducting oxide is formed over the absorber layer and additional barrier or buffer layers are also interposed between the absorber layer and the TCO layer in many examples. The TCO layer is typically covered by a cover glass material that protects the solar cell from the elements.

In order to minimize reflection of sunlight off of any of the layers formed over the absorber layer or the absorber layer itself, anti-reflective coatings (ARC's) are used as coatings over the solar cell.

Commercially available anti-reflective coatings include coatings formed by spin coating and vacuum sputtering deposition methods. These commercially available techniques require high material and equipment costs and are generally formed with non-tunable refractive indices. This is problematic in general and particularly when it is desired to provide an ARC with a desired refractive index for absorbing radiation of a desired wavelength.

The present disclosure addresses the shortcomings of commercially available anti-reflective coatings for solar cells.

### BRIEF DESCRIPTION OF THE DRAWING

The present disclosure is best understood from the following detailed description when read in conjunction with the accompanying drawing. It is emphasized that, according to common practice, the various features of the drawing are not necessarily to scale. On the contrary, the dimensions of the various features are arbitrarily expanded or reduced for clarity. Like numerals denote like features throughout the specification and drawing.

FIG. 1 is a graph that plots molarity of a Zn(NO₃)₂/HMT solution versus length and diameter of nanorods that form the antireflective coating according an embodiment of the disclosure;

FIGS. 2A and 2B are cross sectional views showing a sequence of processing operations for forming one or more antireflective coatings according to an embodiment of the disclosure;

FIGS. 3A and 3B are cross sectional views showing embodiments of an ARC layer formed over a solar cell according to embodiments of the disclosure;

FIGS. 4A and 4B are cross sectional views showing another embodiment with two ARC layers formed on a solar cell according to embodiments of the disclosure;

FIG. 5 shows various SEM micrographs of nanorods formed according to the disclosure and which serve as ARC layers; and

FIG. 6 is a flowchart of a method according to an embodiment of the disclosure.

### DETAILED DESCRIPTION

The disclosure provides methods for forming antireflective layers on solar cells using wet chemical processes and solar cells with anti-reflective layers formed of ZnO based nanorods.

The disclosure utilizes self-assembling nanorods, i.e. tiny rods having dimensions in the nanometer range, and which are generated in the chemical solution without any catalysts. These nanorods grow on the surface exposed to the wet chemical solution, without requiring any catalysts. The self-assembling nanorods are formed to different shapes such as hexagonal, cubic, and circular in cross-section, in various embodiments. The refractive index of the ARC layer formed of the nanorods is modulated by controlling the diameter and length of the nanorods by process tuning. The process tuning is achieved by establishing a correlation between the refractive index and a solution Molarity and preparing and using a solution of a desired Molarity. In some embodiments, the nanorods are formed by contacting a solar cell with an alkali solution including Zn ions. In some embodiments, the nanorods are formed from HMT ([CH₂]₆NH₄) and a dissociative Zn²⁺/OH⁻ chemical compound at various Molarities. In some embodiments, the nanorods are formed from a dissociative Zn²⁺/OH⁻ chemical compound at various Molarities in a solution such as an NH₃ or NH₄ OH alkali solution. In other embodiments, other alkali solutions with Zn ions are used. The Molarity of the [HMT/dissociative Zn²⁺/OH⁻] component in solution is varied to vary the length in nanometers and diameters in nanometers of the nanorods formed and there for the refractive index of the ARC.

In some embodiments, the ARC is formed directly over the TCO layer of a solar cell. The methods and antireflective layers of the disclosure are used to maximize the efficiency of chalcopyrite thin film solar cells and various other types of solar cells.

In some embodiments, an EVA, ethyl vinyl acetate, layer is formed over the ARC layer and a glass cover is formed over the ARC layer. In other embodiments, the glass cover is in place over the TCO layer and the ARC is formed over the glass surface. In some embodiments, two ARC films are formed according to the disclosure. In some embodiments, the two ARC films are formed directly over one another and have different refractive indices.

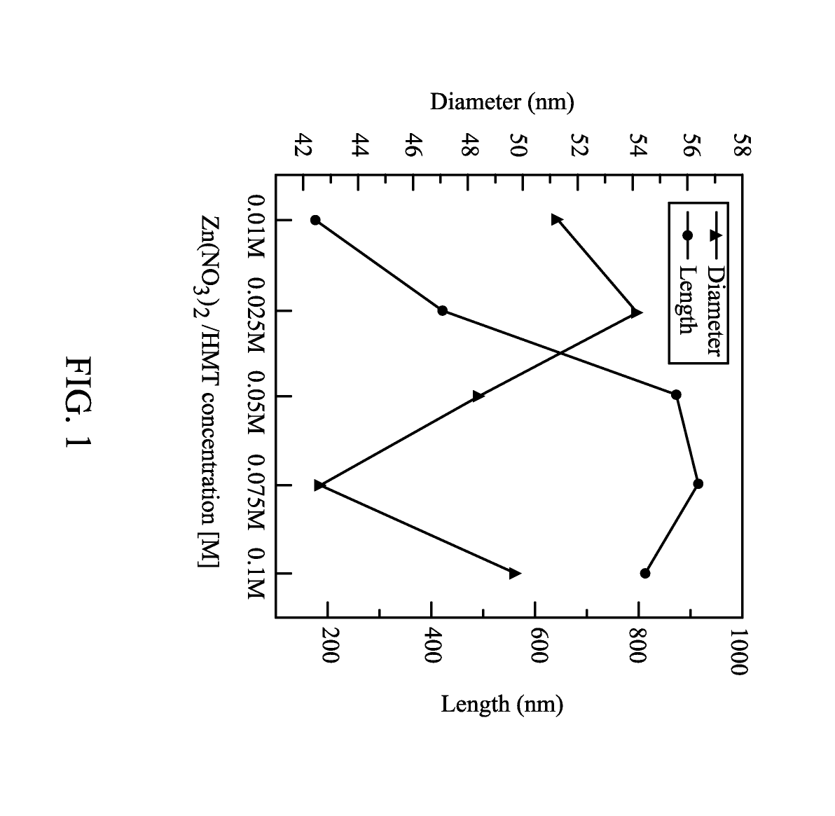

FIG. 1 is a graph showing a correlation between Zn(NO₃)₂/HMT molar concentration in a solution and diameter and length of nanorods formed from the solution. Note that the diameter is presented in nanometers, as is the length, hence the term “nanorods”. FIG. 1 represents one embodiment using Zn(NO₃)₂ and HMT only, and in other embodiments, other solutions that include HMT and a dissociative Zn²⁺/OH⁻ chemical, are used. In various embodiments of the disclosure, the Zn²⁺/OH⁻ dissociative chemical component is ZnCl₂ or ZnSO₄. In one particular embodiment, the Zn²⁺/OH⁻ dissociative chemical component is Zn(NO₃)₂.6H₂O. In other embodiments, other Zn²⁺/OH⁻ dissociative materials are used.

In still other embodiments, other alkali solutions that include Zn ions, are used and in some embodiments, the alkali solution is an NH3 or NH4OH alkali solution. Various Zn-containing dissociative materials are used in various embodiments of the disclosure, to produce the Zn ions.

In each embodiment, the Zn-containing dissociative compound and alkali solution such as HMT([(CH₂)₆NH₄]) are prepared in a specific ratio and the molar concentration of the combination of these two materials is varied within the solution. In some embodiments, the solution is NH₃ and in some embodiments, the solution is a NH₄OH alkali solution, but other solutions are used in other embodiments.

In various embodiments, various Zn²⁺/OH⁻:HMT ratios are used and the molar concentration of the particular ratio is varied to generate a graph with a correlation such as shown in FIG. 1. In some embodiments in which the Zn²⁺/OH⁻ dissociative chemical compound is Zn(NO₃)₂, various Zn(NO₃)₂:HMT ratios are used and the molar concentration of the particular ratio is varied to generate a graph with a correlation such as shown in FIG. 1. Stated alternatively, the graph shown in FIG. 1 of molar concentration versus nanorod diameter and length, is achieved for various different ratios of Zn(NO₃)₂:HMT. In this embodiment, as molar concentration of [Zn2+] and [HMT], increases, rod length decreases and rod diameter increases in some regions. Further, in other embodiments, different Zn²⁺/OH⁻ dissociative chemical compounds are used in combination with HMT. Further still, in other embodiments, different Zn²⁺/OH⁻ dissociative chemical compounds are used in combination with various alkali solutions. A correlation is established between the molar concentration of the solution components of a particular ratio, and the diameter and length of the nanorods. Further, a correlation is established between nanorods having a particular diameter and length, and refractive index. In various embodiments, this correlation may be obtained experimentally, such as by measuring refractive indices. Nanorods having various different configurations are formed according to the disclosure. In some embodiments, the cross-section of the nanorods is hexagonal, and in other embodiments, it is cubic or circular. The disclosure provides, for each Zn(NO₃)₂:HMT ratio, a correlation between solution molarity and refractive index of the anti-reflective coating that is formed of the nanorods.

As such, the disclosure enables one to produce an anti-reflective coating of a desired refractive index by selecting the Zn(NO₃)₂:HMT ratio (or other Zn²⁺/OH⁻:alkali solution ratio) and using a concentration of the Zn(NO₃)₂/HMT in the solution that corresponds to a particular population of nanorods and desired refractive index. In some embodiments, a refractive index of about 1.32 is used, in other embodiments, a refractive index of about 1.37 is used, in other embodiments, a refractive index of about 1.46 is used, but various other refractive indices are used and producible in other embodiments.

The refractive index of the ARC formed with self-assembling nanorods can be modulated by the change of rods' diameter, rods' length and rods' density, i.e. volume fraction, which can be predicted and calculated by the Bruggeman effective medium approximation.

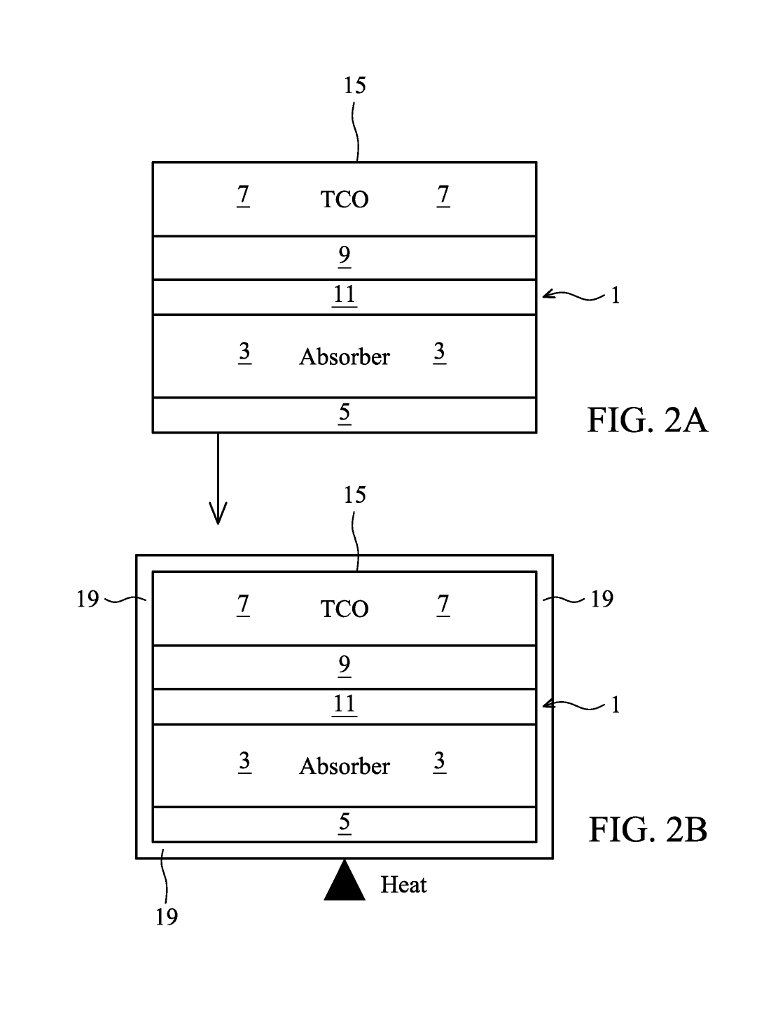

FIG. 2A is a cross-sectional view of an embodiment of a solar cell. Solar cell 1 includes absorber 3 and back contact layer 5. In some embodiments, absorber 3 is a CIGS layer and back contact layer 5 is a molybdenum material, but other materials are used as absorber 3 and back contact layer 5 in other embodiments. Solar cell 1 also includes transparent conducting oxide layer 7. In some embodiments, transparent conducting oxide layer 7 is AZO, aluminum doped ZnO, and in other embodiments, transparent conducting oxide layer 7 is GZO, gallium doped ZnO, and in still other embodiments, transparent conducting oxide layer 7 is BZO, boron doped ZnO or other suitable materials. Between transparent conducting oxide layer 7 and absorber 3 are I—ZnO window layer 9 and buffer layers 11 in some embodiments. In other embodiments, either or both of I—ZnO window layer 9 and buffer layer 11, is not used. Buffer layers 11 may include one or several buffer layers. Absorption surface 15 is the surface through which sunlight enters solar cell 1 and is ultimately absorbed in absorber layer 3, where it is converted to electrical energy.

FIG. 2B shows the solar cell 1 of FIG. 2A immersed in solution 19. The disclosure provides for the solar cell to contact solution 19, and in some embodiments, solar cell 1 is immersed within a solution in a bath, reactor, or other suitable tool. In some embodiments, the immersion takes place in a Teflon reactor, but in other embodiments, other process apparatuses are used. Solution 19 is as discussed above, i.e. solution 19 includes an HMT material in combination with a Zn²⁺/OH⁻ dissociative material such as discussed above in various embodiments. Solution 19 has various molarities as discussed above, and does not require a catalyst. Rather, by contacting solar cell 1 to solution 19, and maintaining an appropriate temperature, nanorods are self-generating. In some embodiments, a temperature within a range of about 50-100 degrees C. is used, and in some embodiments, a temperature within a range of about 70-90 C. is used, and various particular temperatures are used in various embodiments. The contact with solution 19 takes place for times generally within a range of about 30 min to about 360 min depending on desired nanorods' length.

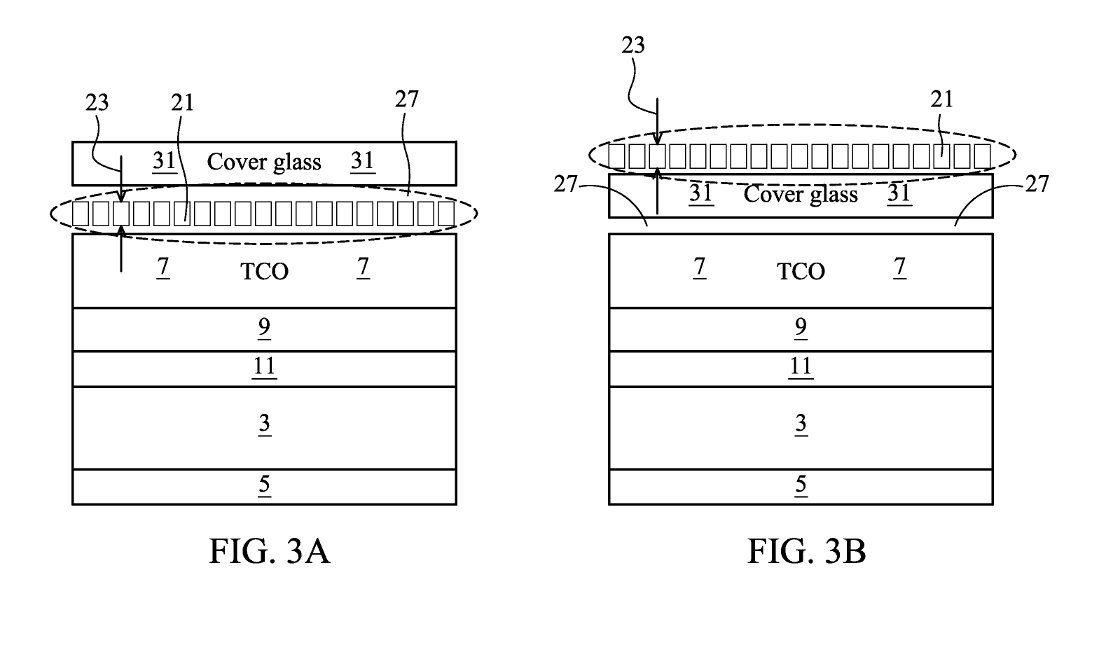

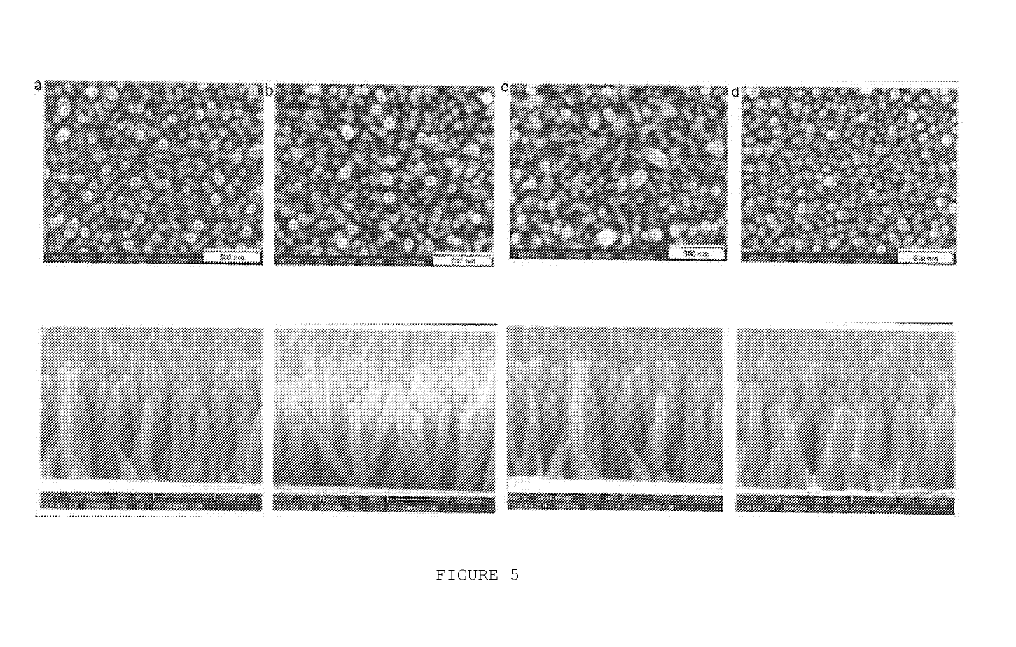

Now turning to FIGS. 3A and 3B, an ARC layer formed by the nanorods is shown. FIG. 3A shows ARC layer 21 formed of a plurality of nanorods, over absorption surface 15 and over TCO layer 7. ARC layer 21 includes a thickness 23 that lies within a range of about 10 nm to about 500 nm in various embodiments, and the nanorods that combine to form ARC layer 21 have various densities, lengths and diameters. Some examples of the nanorods that combine to form ARC layer 21 will be shown in FIG. 5. EVA layer 27 is formed over ARC layer 21 and cover glass 31 is disposed over EVA layer 27.

FIG. 3B shows another embodiment in which EVA layer 27 and cover glass 31 are present before the formation of ARC layer 21. In this embodiment, ARC layer 21 is formed on cover glass 31.

In still another embodiment, two ARC layers are used, one below EVA layer 27 such as shown in FIG. 3A, and one above cover glass 31 such as shown in FIG. 3B.

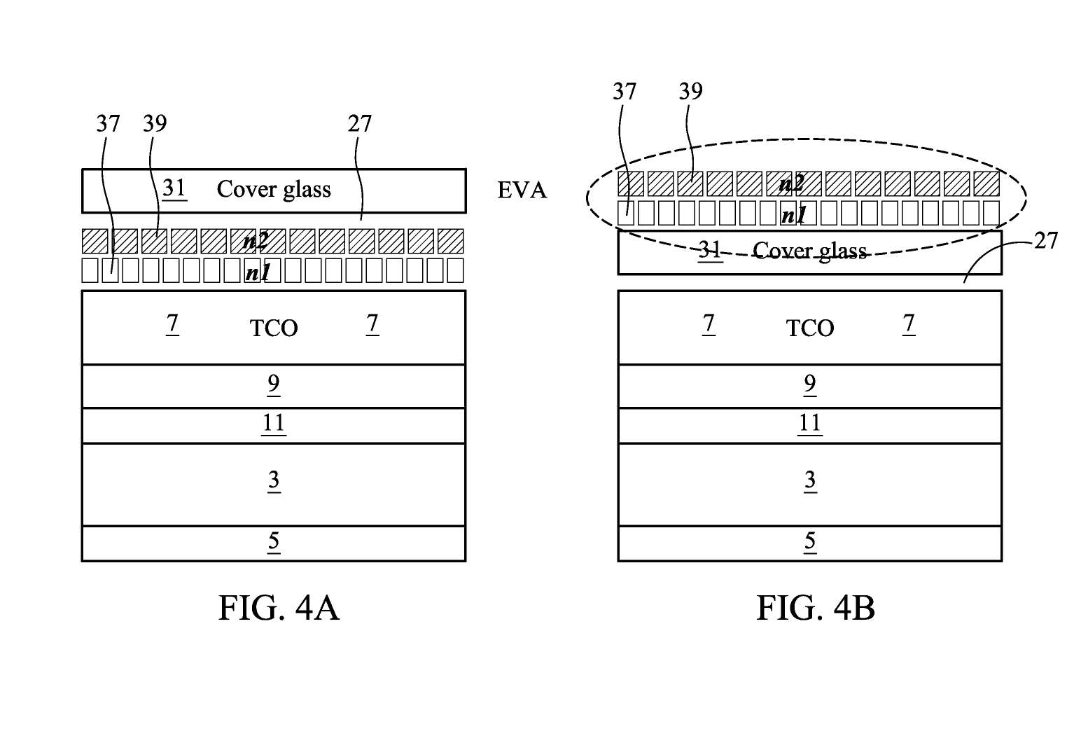

FIGS. 4A and 4B show another embodiment in which two ARC layers are formed. FIG. 4A illustrates an embodiment in which two ARC layers 37 and 39 are formed directly over TCO layer 7 and beneath EVA layer 27 and cover glass 31. FIG. 4B shows an embodiment in which two ARC layers 37 and 39 are formed over cover glass 31. Each of the two ARC layers 37 and 39 is formed after a desired RI is determined, a solution is prepared and a separate deposition operation takes place. According to the embodiment in which two ARC layers are formed, the ARC layers are advantageously formed to have different refractive indices, as indicated by n1 and n2 in FIGS. 4A and 4B, but in some embodiments, the two ARC layers include the same refractive index. Various refractive indices lower than 1.5 are produced in various embodiments. In some embodiments, an ARC layer with a refractive index of about 1.32 is prepared.

FIG. 5 shows various SEM (Scanning Electron Microscope) micrographs of nanorods formed according to the disclosure. The SEM micrographs of FIG. 5 are representative but not limited of the densities and configurations of nanorods formed according to the disclosure. It can be seen that the nanorods in the upper-left hand set of micrographs have essentially a hexagonal cross-section and the nanorods in the upper right-hand corner micrographs also have essentially a hexagonal cross section. The SEM micrographs of FIG. 5, each a set taken in plan view and in perspective view, show various configurations, shapes and densities of the nanorods that combine to form ARC layers according to the disclosure. Various different configurations, diameters and lengths of nanorods are produced, and the various sizes and densities of the ZnO nanorods formed, are determinative of the refractive index of the ARC layer formed at the nanorods.

In some embodiments, the ZnO nanorods have lengths ranging from about 200 to about 900 nm, diameters within a range of about 40-60 nm, and the ZnO nanorods have a rod density of about 1.0 g/cm2 to about 10³ g/cm2.

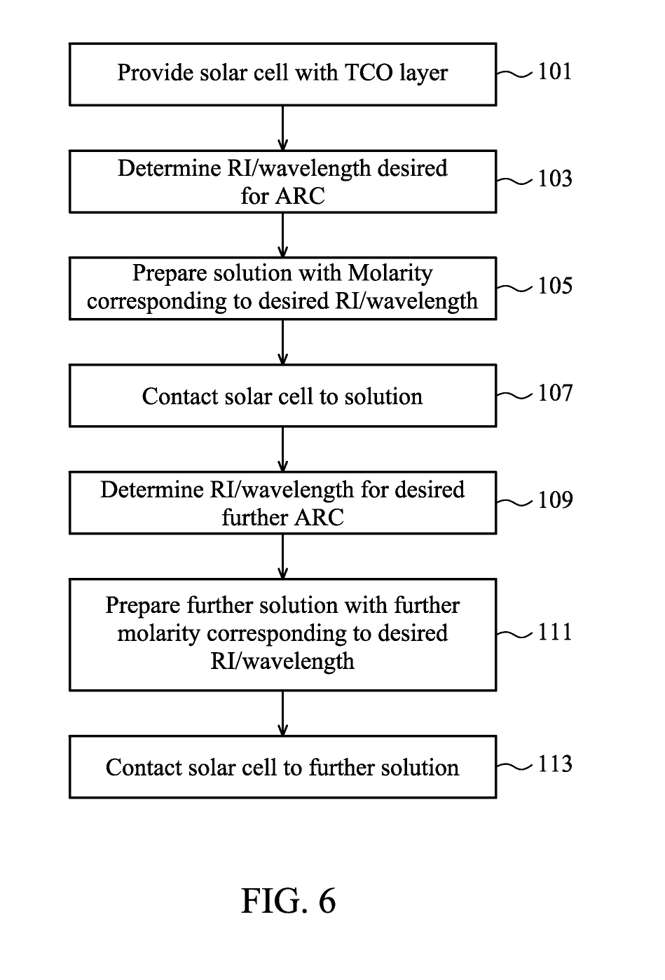

FIG. 6 is a flowchart showing the series of steps used to form an anti-reflective coating that has a desired refractive index, on a solar cell. As stated above, various different solar cell types are used, including, but not limited to chalcopyrite-based absorber material solar cells.

A solar cell with a transparent conducting oxide, i.e. TCO layer is provided at “Provide solar cell with TCO layer” step 101. The desired refracted index and wavelength of absorption is determined at “Determine RI/wavelength desired for ARC” step 103. At step 105, “Prepare solution with molarity corresponding to desired RI/wavelength”, the correlation between desired refractive index and solution concentration such as shown in FIG. 1, is used. A solution is prepared with the Molarity that will produce the desired refractive index, based upon the correlation. As discussed above, the solution is an alkali solution incorporated with Zn ions. At “Contact solar cell to solution” step 107, the solar cell is immersed in a reactor or otherwise contacted to the solution and retained at a desired temperature, generally in the range of about 70-90° C. in various embodiments. In some embodiments, a teflon reactor is used to carry out the reaction step in which the solar cell contact the solution and in which the ARC layer is created, and in other embodiments, other reactors or other wet chemical baths are used. At step 107, the anti-reflective coating is formed. In some embodiments, the ARC layer disposed on the TCO layer, and it is formed over the cover glass disposed over an EVA layer disposed over the TCO layer, in some embodiments.

In some embodiments in which only one ARC layer is formed, steps 109, 111 and 113 are not needed.

In some embodiments in which a second ARC layer is desired, “Determine RI/wavelength for desired further ARC” step 109 is carried out for the formation of a second ARC layer, generally directly on the first ARC layer. At “Prepare further solution with further molarity corresponding to desired RI/wavelength” step 111, a further solution is formed based on a correlation between desired refractive index and solution molarity as discussed above. The further solution is prepared in a different bath or reactor in various embodiments. At “Contact solar cell to further solution step” 113, the solar cell is contacted to a solution such as by immersion in a teflon or other reactor and the further ARC is formed. In some embodiments, the first ARC and further ARC have different refractive indices.

According to some aspects, a method for forming an anti-reflective coating on a solar cell, is provided. The method comprises: providing a solar cell with a TCO (transparent conductive oxide) layer and a cover glass thereover; and forming an ARC (anti-reflective coating) by contacting the solar cell with an alkali solution including Zn ions, and maintaining the solution at a temperature within a range of about 50-100° C.

In some embodiments, the alkali solution including Zn ions comprises HMT ([CH₂]₆NH₄) and a dissociative Zn²⁺/OH⁻ chemical component.

In some embodiments, the contacting comprises immersing the solar cell in the solution and the dissociative Zn²⁺/OH⁻ chemical component comprises Zn(NO₃)₂.6H₂O.

In some embodiments, the dissociative Zn²⁺/OH⁻ chemical component comprises at least one of ZnCl₂, Zn(NO₃)₂, and ZnSO₄.

In some embodiments, the alkali solution including Zn ions includes the HMT ([CH₂]₆NH₄) and the dissociative Zn²⁺/OH⁻ chemical component having a combined molarity of about 0.01 M to 0.1 M.

In some embodiments, the TCO comprises one of AZO(ZnO:Al), GZO(ZnO:Ga) and BZO(ZnO:B), the solution has a molarity between about 0.01 M and 0.1 M, and the forming includes maintaining the temperature within a range of about 70-90° C.

In some embodiments, the alkali solution including Zn ions comprises an NH3 or NH4OH alkali solution with a molarity of about 0.01 M to 0.1 M.

In some embodiments, the step of providing further comprises an EVA (ethyl vinyl acetate) film between the TCO and the ARC.

In some embodiments, the step of providing further includes forming a further ARC (anti-reflective coating) on the TCO layer and beneath the cover glass, by contacting the solar cell with a further alkali solution including Zn ions, and maintaining the solution at a temperature within a range of about 50-100° C.

In some embodiments, a refractive index of the further ARC is less than a refractive index of the ARC.

According to another aspect, method for forming a solar cell, is provided. The method comprises: providing a solar cell with a TCO (transparent conductive oxide) layer; determining a desired RI (refractive index) for an ARC (antireflective coating) to be formed on the solar cell; preparing an alkali solution including Zn ions and having a Molarity of about 0.01 M to about 0.1 M and associated with the desired RI; forming the ARC by immersing the solar cell in the alkali solution and maintaining the alkali solution at a temperature of about 70-90° C.; preparing a further alkali solution including Zn ions and having a further Molarity of about 0.01 M to about 0.1 M and associated with a desired further RI for a further ARC; and forming the further ARC by immersing the solar cell in the further alkali solution and maintaining the further alkali solution at a temperature of about 70-90° C., wherein the RI and the further RI differ.

In some embodiments, the desired RI is less than the desired further RI.

In some embodiments, the alkali solution including Zn ions includes HMT ([CH₂]₆NH₄) and a dissociative Zn²⁺/OH⁻ chemical component.

In some embodiments, the dissociative Zn²⁺/OH⁻ chemical component comprises Zn(NO₃)₂.6H₂O.

In some embodiments, the method further comprises establishing a correlation between the Molarity and the desired RI and wherein the Molarity is associated with the desired RI.

In some embodiments, the alkali solution including Zn ions and the further alkali solution including Zn ions each include a dissociative Zn²⁺/OH⁻ chemical component in an NH₃ or NH₄OH alkali solution.

A solar cell is also provided. The solar cell comprises: a solar cell substructure including an absorber layer and a TCO (transparent conductive oxide) layer over the absorber layer; an ARC (antireflective coating) disposed over the TCO layer of the solar cell and including a plurality of ZnO nanorods having lengths within a range of about 200 to about 900 nm, diameters within a range of about 40-60 nm, and a density of about 1.0 g/cm2 to about 10³ g/cm2; and a further ARC disposed over the ARC, the further ARC including a plurality of ZnO nanorods having lengths within a range of about 200 to about 900 nm and diameters within a range of about 40-60 nm, wherein the ARC and the further ARC have different refractive indexes and each has a refractive index lass than about 1.5.

In some embodiments, the absorber layer comprises a chalcopyrite-based absorber layer, the TCO comprises AZO (aluminum doped ZnO) and the ARC has a refractive index less than a refractive index of the further ARC.

In some embodiments, the solar cell substructure further comprises a glass cover over the TCO layer, and wherein the ARC is formed on the glass cover.

In some embodiments, the solar cell substructure further comprises a glass cover over the TCO layer and the ARC is formed on the TCO layer and the further ARC layer is formed on the glass cover.

The preceding merely illustrates the principles of the disclosure. It will thus be appreciated that those skilled in the art will be able to devise various arrangements which, although not explicitly described or shown herein, embody the principles of the disclosure and are included within its spirit and scope. Furthermore, all examples and conditional language recited herein are principally intended expressly to be only for pedagogical purposes and to aid the reader in understanding the principles of the disclosure and the concepts contributed by the inventors to furthering the art, and are to be construed as being without limitation to such specifically recited examples and conditions. Moreover, all statements herein reciting principles, aspects, and embodiments of the disclosure, as well as specific examples thereof, are intended to encompass both structural and functional equivalents thereof. Additionally, it is intended that such equivalents include both currently known equivalents and equivalents developed in the future, i.e., any elements developed that perform the same function, regardless of structure.

This description of the exemplary embodiments is intended to be read in connection with the figures of the accompanying drawing, which are to be considered part of the entire written description. In the description, relative terms such as “lower,” “upper,” “horizontal,” “vertical,” “above,” “below,” “up,” “down,” “top” and “bottom” as well as derivatives thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

Although the disclosure has been described in terms of exemplary embodiments, it is not limited thereto. Rather, the appended claims should be construed broadly, to include other variants and embodiments of the disclosure, which may be made by those skilled in the art without departing from the scope and range of equivalents of the disclosure.

What is claimed is:

1. A method for forming an anti-reflective coating on a solar cell, said method comprising:
providing a solar cell with a TCO (transparent conductive oxide) layer and a cover glass thereover; and
forming an ARC (anti-reflective coating) by contacting said solar cell with an alkali solution including Zn ions, and maintaining said solution at a temperature within a range of about 50-100° C.

2. The method as in claim 1, wherein said alkali solution including Zn ions comprises HMT ([CH₂]₆NH₄) and a dissociative Zn²⁺/OH⁻ chemical component.

3. The method as in claim 2, wherein said contacting comprises immersing said solar cell in said solution and said dissociative Zn²⁺/OH⁻ chemical component comprises Zn(NO₃)₂.6H₂O.

4. The method as in claim 2, wherein said dissociative Zn²⁺/OH⁻ chemical component comprises at least one of ZnCl₂, Zn(NO₃)₂, and ZnSO₄.

5. The method as in claim 2, wherein said alkali solution including Zn ions includes said HMT ([CH₂]₆NH₄) and said dissociative Zn²⁺/OH⁻ chemical component having a combined molarity of about 0.01 M to 0.1 M.

6. The method as in claim 1, wherein said TCO comprises one of AZO(ZnO:Al), GZO(ZnO:Ga) and BZO(ZnO:B), said solution has a molarity between about 0.01 M and 0.1 M, and said forming includes maintaining said temperature within a range of about 70-90° C.

7. The method as in claim 1, wherein said alkali solution including Zn ions comprises an NH3 or NH4OH alkali solution with a molarity of about 0.01 M to 0.1 M.

8. The method as in claim 1, wherein said providing further comprises an EVA (ethyl vinyl acetate) film between said TCO and said ARC.

9. The method as in claim 1, wherein said providing further includes forming a further ARC (anti-reflective coating) on said TCO layer and beneath said cover glass, by contacting said solar cell with a further alkali solution including Zn ions, and maintaining said solution at a temperature within a range of about 50-100° C.

10. The method as in claim 9, wherein a refractive index of said further ARC is less than a refractive index of said ARC.

11. A method for forming a solar cell, said method comprising:
providing a solar cell with a TCO (transparent conductive oxide) layer;
determining a desired RI (refractive index) for an ARC (antireflective coating) to be formed on said solar cell;
preparing an alkali solution including Zn ions and having a Molarity of about 0.01 M to about 0.1 M and associated with said desired RI;
forming said ARC by immersing said solar cell in said alkali solution and maintaining said alkali solution at a temperature of about 70-90° C.;
preparing a further alkali solution including Zn ions and having a further Molarity of about 0.01 M to about 0.1 M and associated with a desired further RI for a further ARC; and
forming said further ARC by immersing said solar cell in said further alkali solution and maintaining said further alkali solution at a temperature of about 70-90° C.,
wherein said RI and said further RI differ.

12. The method as in claim 11, wherein said desired RI is less than said desired further RI.

13. The method as in claim 11, wherein said alkali solution including Zn ions includes HMT ([CH₂]₆NH₄) and a dissociative Zn²⁺/OH⁻ chemical component.

14. The method as in claim 13, wherein said dissociative Zn²⁺/OH⁻ chemical component comprises Zn(NO₃)₂.6H₂O.

15. The method as in claim 11, further comprising establishing a correlation between said Molarity and said desired RI and wherein said Molarity is associated with said desired RI.

16. The method as in claim 11 wherein said alkali solution including Zn ions and said further alkali solution including Zn ions each include a dissociative Zn²⁺/OH⁻ chemical component in an NH₃ or NH₄OH alkali solution.

17. A solar cell comprising:
a solar cell substructure including an absorber layer and a TCO (transparent conductive oxide) layer over said absorber layer;
an ARC (antireflective coating) disposed over said TCO layer of said solar cell and including a plurality of ZnO nanorods having lengths within a range of about 200 to about 900 nm, diameters within a range of about 40-60 nm, and a density of about 1.0 g/cm2 to about 10³ g/cm2; and
a further ARC disposed over said ARC, said further ARC including a plurality of ZnO nanorods having lengths within a range of about 200 to about 900 nm and diameters within a range of about 40-60 nm,
wherein said ARC and said further ARC have different refractive indexes and each has a refractive index lass than about 1.5.

18. The solar cell as in claim 17, wherein said absorber layer comprises a chalcopyrite-based absorber layer, said TCO comprises AZO (aluminum doped ZnO) and said ARC has a refractive index less than a refractive index of said further ARC.

19. The solar cell as in claim 18, wherein said solar cell substructure further comprises a glass cover over said TCO layer, and wherein said ARC is formed on said glass cover.

20. The solar cell as in claim 18, wherein said solar cell substructure further comprises a glass cover over said TCO layer and said ARC is formed on said TCO layer and said further ARC layer is formed on said glass cover.
